(19) United States
(12) Patent Application Publication
(10) Pub. No.: US 2025/0176368 A1
(43) Pub. Date: May 29, 2025

(54) DISPLAY PANEL AND DISPLAY DEVICE

(71) Applicant: HKC CORPORATION LIMITED, SHENZHEN (CN)

(72) Inventors: Yao LI, SHENZHEN (CN); Haijiang YUAN, SHENZHEN (CN)

(73) Assignee: HKC CORPORATION LIMITED, SHENZHEN (CN)

(21) Appl. No.: 18/950,093

(22) Filed: Nov. 17, 2024

(30) Foreign Application Priority Data
Nov. 24, 2023 (CN) 202311594508.4

(51) Int. Cl. H10K 59/122; H10K 102/00

(52) U.S. Cl. CPC H10K 59/122; H10K 2102/311

(57) ABSTRACT

The present application provides a display panel and a display device. According to the application, the elastic metal structure is embedded in the middle insulation part of the conductive isolation structure and is electrically connected with the conductive part. Secondly, the first metal structure in the elastic metal structure is at least located in the stretchable area and extends in the first preset direction; and the second metal structure in the elastic metal structure is arranged in the island area.

### CROSS-REFERENCE TO RELATED APPLICATIONS

The present application claims priority to Chinese Patent Application No. 202311594508.4, filed Nov. 24, 2023, which is herein incorporated by reference in its entirety.

### TECHNICAL FIELD

The present disclosure relates to the technical field of display technologies, and in particular to a display panel and a display device.

### BACKGROUND

Organic light emitting diodes (OLEDs) have advantages of surface light source, cold light, energy saving, fast response, flexibility, ultra-light, low cost and the like, and technology for mass production is becoming increasingly mature. Usually, an OLED light-emitting layer is composed of three light-emitting films emitting light of RGB (red, green, blue). In the process of preparing the three light-emitting films, it is required to use a separation grid (separation pillar) of a substrate for the process of printing and patterning.

As a new form of display device, flexible stretchable display screens have attracted widespread attention from consumers, and may be applied to multiple scenarios in actual use due to their variable display size. In recent years, stretchable display devices that can extend/contract in a specific direction and change to a fixed shape by forming display pixel units, connecting wires, and light-emitting units on a flexible substrate of organic materials have been widely used as a new generation of display devices. For stretchable display products, when the screen is stretched, the internal film structure may also be subjected to a certain amount of tension. Therefore, it is crucial to improve the stability of the stretchable display products.

### SUMMARY

A first technical solution provided by the present disclosure is a display panel including an island area and a stretchable area located at the side of the island area, the display panel further includes a pixel definition layer, a sub-pixel, a conductive isolation structure; the pixel definition layer covers the island area and the stretchable area; the pixel definition layer has a pixel aperture located at the island area, the pixel aperture and an adjacent pixel aperture are arranged at intervals; the sub-pixel is located in the pixel aperture; the conductive isolation structure is protruded from the pixel definition layer and located at the side of the sub-pixel; the conductive isolation structure includes a conductive part, a middle insulating part and a top insulating part which are sequentially stacked in a direction away from the pixel definition layer; the conductive isolation structure is located at the island area and the stretchable area; the conductive part is provided in contact with and conductive to a cathode of the adjacent sub-pixel; the display panel further includes an elastic metal structure embedded in the middle insulating part and electrically connected to the conductive part; the elastic metal structure includes at least one first elastic metal structure; the first elastic metal structure includes a first metal structure at least located at the stretchable area and a second metal structure located at the island area; the first metal structure is extended along a first preset direction, and the second metal structure supports the first metal structure along a thickness direction of the pixel definition layer; the first preset direction is perpendicular to the thickness direction of the pixel definition layer and parallel to a plane direction of the pixel definition layer.

A second technical solution provided by the present disclosure is a display device, and the display device comprises the display panel mentioned above.

### BRIEF DESCRIPTION OF THE DRAWINGS

In order to more clearly illustrate the technical solutions in the embodiments of the present disclosure, the figures required for the description of the embodiments will be briefly introduced below. Obviously, the figures described below are only some embodiments of the present disclosure. For those skilled in the art, other figures may be obtained based on these figures without any creative work.

FIG. 1 is a schematic structural diagram of an embodiment of a display panel provided by the present disclosure.

FIG. 2 is a schematic structural diagram of a first embodiment of the display panel provided by the present disclosure.

FIG. 3 is a schematic structural top plan view of an elastic metal structure in FIG. 2.

FIG. 4 is a schematic longitudinal cross-sectional structural view of a first elastic metal structure in FIG. 2.

FIG. 5 is a schematic structural top plan view of the first elastic metal structure in FIG. 2.

FIG. 6 is a schematic structural top plan view of an elastic metal structure of a second embodiment of the display panel provided by the present disclosure.

FIG. 7 is a schematic structural diagram of a third embodiment of the display panel provided by the present disclosure.

FIG. 8 is schematic structural top plan view of an elastic metal structure in FIG. 7.

FIG. 9 is a schematic longitudinal cross-sectional structural view of a first elastic metal structure in FIG. 7.

FIG. 10 is a schematic structural top plan view of the first elastic metal structure in FIG. 7.

### DETAILED DESCRIPTIONS

The solutions of the embodiments of the present disclosure are described in detail below in conjunction with the figures of the specification.

In the following description, for the purpose of explanation rather than limitation, specific details such as specific system structures, interfaces, and technologies are provided to facilitate a thorough understanding of the present disclosure.

The following will be combined with the figures of the embodiments provided by the present disclosure to clearly and completely describe the technical solutions in the embodiments of the present disclosure. Obviously, the described embodiments are only part of the embodiments of the present disclosure, not all of the embodiments. Based on the embodiments provided by the present disclosure, all other embodiments obtained by person having ordinary skill in the art without creative work will fall into the scope of protection of the present disclosure.

The terms “first”, “second”, “third” in the present disclosure are only used for describing, and cannot be understood as indicating or implying relative importance or implicitly indicating the number of indicated technical features. Thus, the features defined as “first”, “second”, “third” may expressly or implicitly include at least one of the features. In the description of this disclosure, the meaning of “plurality of” is at least two, such as two, three, etc., unless clearly and specifically defined. In the embodiments of the present disclosure, all directional indications (such as up, down, left, right, front, back . . . ) are only used to explain relative position relationships, movements, etc. between the components in a certain specific posture (as shown in the accompanying figures). If the specific posture changes, the directional indication also changes accordingly. In addition, the terms “including” and “having” and any of their variations are intended to cover non-exclusive inclusions. For example, a process, method, system, product or device that includes a series of steps or units is not limited to the steps or units listed, but optionally also includes steps or units that are not listed, or optionally also includes other steps or units inherent to these processes, methods, products or devices.

Reference to “embodiments” herein means that a particular feature, structure, or characteristic described in the embodiments may be included in at least one embodiment of the present disclosure. The appearance of the phrase in various locations in the specification does not necessarily refer to the same embodiment, nor is it an independent or alternative embodiment that is mutually exclusive with other embodiments. It is explicitly and implicitly understood by those skilled in the art that the embodiments described herein may be combined with other embodiments.

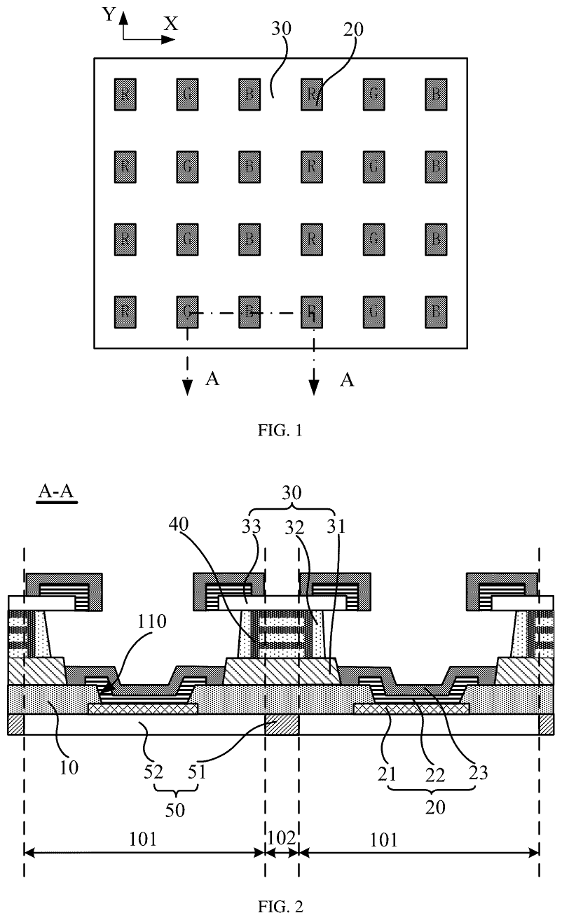

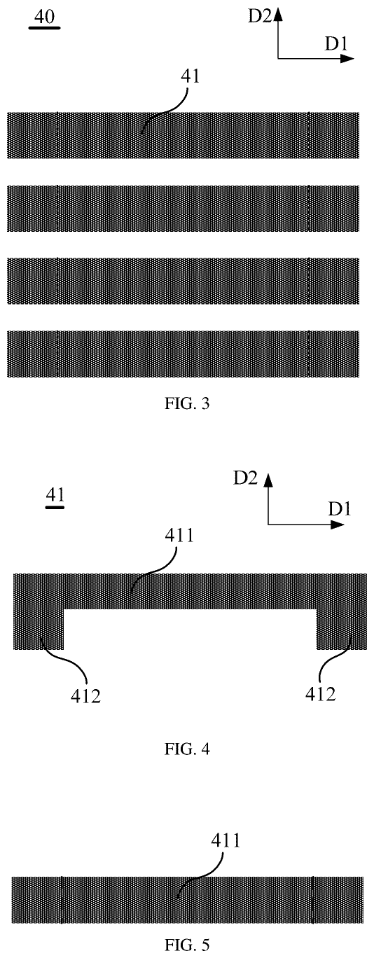

Please refer to FIG. 1 to FIG. 5, FIG. 1 is a schematic structural diagram of an embodiment of a display panel provided by the present disclosure, FIG. 2 is a schematic structural diagram of a first embodiment of a display panel provided by the present disclosure, FIG. 3 is a schematic structural top plan view of an elastic metal structure in FIG. 2, FIG. 4 is a schematic longitudinal cross-sectional structural view of a first elastic metal structure in FIG. 2, and FIG. 5 is a schematic structural top plan view of a first elastic metal structure in FIG. 2.

The present disclosure provides a display panel. The display panel is a stretchable display panel. The display panel includes an island area 101 and a stretchable area 102 located at the side of the island area 101. The display panel further includes a pixel definition layer 10, a sub-pixel 20 and a conductive isolation structure 30. The pixel definition layer 10 covers the island area 101 and the stretchable area 102. The pixel definition layer 10 has a pixel aperture 110 located at the island area 101, the pixel aperture and an adjacent pixel aperture are arranged at intervals. The sub-pixel 20 is located in one of the pixel apertures 110. The conductive isolation structure 30 is protruded from the pixel definition layer 10 and located at the side of the sub-pixel 20. The conductive isolation structure 30 includes a conductive part 31, a middle insulating part 32 and a top insulating part 33 that are sequentially stacked in a direction away from the pixel definition layer 10. The conductive isolation structure 30 is located at the island area 101 and the stretchable area 102. The conductive part 31 is provided in contact with and conductive to a cathode 23 of the adjacent sub-pixel 20.

The display panel may further include an elastic metal structure 40 embedded in the middle insulating part 32 and electrically connected to the conductive part 31. The elastic metal structure 40 may include at least one first elastic metal structure 41. The first elastic metal structure 41 may include a first metal structure 411 at least located at the stretchable area 102 and a second metal structure 412 located at the island area 101. The first metal structure 411 may be extended along a first preset direction D1, and the second metal structure 412 may support the first metal structure 411 along a thickness direction of the pixel definition layer 10. The first preset direction D1 may be perpendicular to the thickness direction of the pixel definition layer 10 and parallel to a plane direction of the pixel definition layer 10.

In the present disclosure, the elastic metal structure 40 may be embedded in the middle insulating part 32 of the conductive isolation structure 30 and be electrically connected to the conductive part 31, which may increase the height of the conductive part 31 of the conductive isolation structure 30, then reduce the impedance of the conductive part 31 and the connection impedance among the cathodes 23 of the sub-pixels 20, and therefore be beneficial to improving the signal uniformity of the cathodes 23. Secondly, in the present disclosure, the first metal structure 411 in the elastic metal structure 40 is at least located at the stretchable area 102 and is extended along the first preset direction D1, so that the extension direction of the first metal structure 411 is consistent with the direction in which the first metal structure 411 is stretched, thereby improving the stability of the first metal structure 411, and further facilitating the improvement of the stability of the part of the middle insulating part 32 of the conductive isolation structure 30 located in the stretchable area 102. In addition, the second metal structure 412 in the elastic metal structure 40 is located at the island area 101, which may not only play a role in supporting the first metal structure 411, but also improve the rigidity of the part of the middle insulating part 32 located in the island area 101, and further improve the anti-stretching stability of the part of the middle insulating part 32 located in the island area 101.

One island area 101 may include at least one sub-pixel 20. When the island area 101 includes a plurality of sub-pixels 20, the connection among the cathodes 23 of the plurality of sub-pixels 20 is not limited here and may be selected according to actual needs. The manufacture of the cathodes 23 of the plurality of sub-pixels 20 in one island area 101 may adopt the FMM (Fine Metal Mask) process or a process without FMM.

In this embodiment, one island part 101 including one sub-pixel 20 is used as an example for description.

The pixel definition layer 10 may be configured to define the position of the sub-pixel 20. The thickness and material of the pixel definition layer 10 are not limited here and may be selected according to actual needs.

The sub-pixel 20 may include an anode 21, a light-emitting layer 22 and the cathode 23 which are stacked in sequence. One sub-pixel 20 may correspond to one color pixel. The arrangement of the sub-pixels 20 and the color of the color pixel corresponding to the sub-pixel 20 are not limited here, and may be selected according to actual needs.

In this embodiment, the display panel includes sub-pixels 20 of three different colors, namely red pixels, blue pixels and green pixels. The sub-pixels 20 may be arranged in an array. Specifically, the sub-pixels 20 of three different colors are alternately arranged in a first direction X, and the sub-pixels 20 are repeatedly arranged in a second direction Y.

The first preset direction D1 in the present disclosure is not a fixed direction, but is related to the position of the conductive isolation structure 30.

When the conductive isolation structure 30 is located at the side of the sub-pixel 20 along the first direction X, the first preset direction D1 is parallel to the first direction X; when the conductive isolation structure 30 is located at the side of the sub-pixel 20 along the second direction Y, the first preset direction D1 is parallel to the second direction Y. The first preset direction D1 is the direction in which the conductive isolation structure 30 is stretched when the display panel is stretched along a certain direction.

The conductive isolation structure 30 includes the conductive part 31, the middle insulating part 32 and the top insulating part 33 which are sequentially stacked in a direction away from the pixel definition layer 10. The orthographic projection of the top insulating part 33 on the pixel definition layer 10 covers the orthographic projection of the conductive part 31 on the pixel definition layer 10 and the orthographic projection of the middle insulating part 32 on the pixel definition layer 10. The cross section of the middle insulating part 32 in the thickness direction of the pixel definition layer 10 may be a trapezoid, and the width of the middle insulating part 32 gradually decreases in a direction toward the top insulating part 33, so that other subsequent film layers are attached to the sidewall of the middle insulating part 32. The projection area of the top insulating part 33 on the pixel definition layer 10 may be larger than the projection area of the conductive part 31 on the pixel definition layer 10, and the orthographic projection of the middle insulating part 32 on the conductive part 31 is inside the conductive part 31, so that when evaporating the sub-pixel 20, the evaporation angle can be adjusted through the top insulating part 33 and the cathode 23 of the sub-pixel 20 covers the end of the light-emitting layer 22, so as to achieve good electrical connection with the conductive part 31.

The middle insulating part 32 includes organic insulating material, and the top insulating part 33 includes elastic insulating material.

At least one elastic metal structure 40 is embedded in the middle insulating part 32 of one conductive isolation structure 30. When the number of the elastic metal structures 40 is a plurality, the elastic metal structures 40 are stacked and aligned in the thickness direction of the pixel definition layer 10. The plurality of elastic metal structures 40 are electrically connected with each other. The plurality of elastic metal structures 40 are overlapped in the thickness direction of the pixel definition layer 10, and the elastic metal structures 40 are contacted with each other to be electrically connected with each other.

The material of the elastic metal structure 40 may be the same as or different from which of the conductive part 31. The material of the elastic metal structure 40 is not limited here and may be selected according to actual needs.

The number of the elastic metal structures 40 depends on the height of the middle insulating part 32.

The elastic metal structure 40 close to the conductive part 31 may be in contact with the conductive part 31 to achieve electrical connection between the elastic metal structure 40 and the conductive part 31.

The elastic metal structure 40 may include at least one first elastic metal structure 41. Without affecting the spacing of the sub-pixels 20 with each other, the more the number of first elastic metal structures 41 is, the better the stability of the middle insulating part 32 in which the elastic metal structure 40 is embedded.

In this embodiment, the number of the first elastic metal structures 41 is a plurality. The plurality of first elastic metal structures 41 are arranged at intervals along a second preset direction D2.

The second preset direction D2 intersects the first preset direction D1 and is parallel to the plane direction of the pixel definition layer 10. The plane where the first preset direction D1 and the second preset direction D2 lie is parallel to the plane direction of the pixel definition layer 10.

The first metal structure 411 is at least located in the stretchable area 102, which can be understood as the first metal structure 411 being only located in the stretchable area 102. The first metal structure 411 may also be located in the stretchable area 102 and extend from the stretchable area 102 to the island area 101. That is, the first metal structure 411 may be located in the stretchable area 102 and the island area 101.

In this embodiment, the first metal structure 411 is located in the stretchable area 102 and in the island area 101 adjacent to the stretchable area 102. The first metal structure 411 is extended along the first preset direction D1, so that the extension direction of the first metal structure 411 is consistent with the first preset direction D1, that is, the extension direction of the first metal structure 411 is consistent with the direction in which the conductive isolation structure 30 is stretched, the stability of the first metal structure 411 may therefore be improved, and then the stability of the middle insulating part 32 of the conductive isolation structure 30 located in the stretchable area 102 may be improved.

The second metal structure 412 is located at the island area 101 and supports the first metal structure 411, so that the first metal structure 411 is suspended relative to the conductive part 31, and the middle insulating part 32 can be filled between the first metal structure 411 and the conductive part 31, when the first metal structure 411 is stretched, the middle insulating part 32 may therefore share stress generated by deformation, and force stability of the first metal structure 411 in the thickness direction of the pixel definition layer 10 may therefore be ensured. Similarly, the second metal structure 412 supports the first metal structure 411, so that the middle insulating part 32 may be also filled between two adjacent first metal structures 411 after the elastic metal structure 40 is stacked, which may also improve the force stability of the first metal structure 411 in the thickness direction of the pixel definition layer 10.

In this embodiment, the second metal structure 412 is located in a side of the first metal structure 411 close to the pixel definition layer 10, and is extended along the thickness direction of the pixel definition layer 10. The number of the second metal structures 412 in the first elastic metal structure 41 is two, and the two second metal structures 412 may be arranged side by side and at intervals along the first preset direction D1, and be respectively connected to ends of the first metal structure 411. An end of one of the two second metal structures 412 is connected to an end of the first metal structure 411 along the first preset direction D1, and an end of the other second metal structure 412 of the two second metal structures 412 is connected to the other end of the first metal structure 411 along the first preset direction D1. The other ends of the two second metal structures 412 are both arranged in the direction of the pixel definition layer 10.

In some embodiments, the first metal structure 411 and the second metal structure 412 are provided vertically, so that uniform force of the second metal structure 412 in a direction parallel to the pixel definition layer 10 may be achieved, which is beneficial to improving the stability of the second metal structure 412.

Since the middle insulating part 32 includes organic insulating material, the toughness may be relatively weak. Through providing the second metal structure 412 in the island area 101 and embedding the second metal structure 412 in the middle insulating part 32, improvement of the rigidity of the part of the middle insulating part 32 located in the island area 101 may be achieved, and improvement of tensile stability of the part of the conductive isolation structure 30 located in the island area 101 may therefore be achieved.

The height of the second metal structure 412 may be 1 micron to 1.5 microns, and the width of the second metal structure 412 may be 3 microns to 4 microns. When the width of the second metal structure 412 is too large, the width of the middle insulating part 32 of the conductive isolation structure 30 may increase, which is not conducive to improving the pixel aperture ratio. When the width of the second metal structure 412 or the height of the second metal structure 412 is too small, the rigidity of the second metal structure 412 may be weak, which is not conducive to improving the tensile stability of the part of the conductive isolation structure 30 located in the island area 101. When the height of the second metal structure 412 is too large, it is not conducive to the preparation of the first metal structure 411.

The thickness of the first metal structure 411 may be 3000 angstroms to 5000 angstroms. When the thickness of the first metal structure 411 is too large, it is not conducive to the preparation of the plurality of elastic metal structures 40; when the thickness of the first metal structure 411 is too small, it is not conducive to improving the stability of the first metal structure 411.

The first elastic metal structure 41 may be integrally formed. In other words, the first metal structure 411 and the second metal structure 412 are integrally formed, which may further improve the stability of the first elastic metal structure 41.

In some embodiments, the middle insulating part 32 may be prepared from a plurality of middle insulating layers. One middle insulating layer may be prepared on the conductive part 31 using nanoimprint lithography, and then two via holes are provided at intervals on the middle insulating layer, the via holes penetrate the middle insulating layer and are located in the island area 101. The width of the via holes may be 3 microns to 4 microns. That is, the width of the second metal structure 412 may be 3 microns to 4 microns. A through groove may be provided on the middle insulating layer between the via holes, and the distance between the lower surface of the middle insulating layer and the base wall of the through groove may be 1 micron to 1.5 microns. That is, the height of the second metal structure 412 may be 1 micron to 1.5 microns. The side wall of the via hole away from the through groove may function as a barrier for leveling of subsequent material. Material of the elastic metal structure 40 may be filled into the via hole and the through groove using inkjet printing to form the first elastic metal structure 41. That is, the first metal structure 411 and the second metal structure 412 of the first elastic metal structure 41 are all formed using one-step forming process, so that the film strength of the first elastic metal structure 41 may be improved. The above operations are repeated to form a stack of the elastic metal structure 40 in the thickness direction of the pixel definition layer 10 and complete the preparation of the middle insulating part 32.

In other embodiments, the first elastic metal structure 41 may further include a third metal structure 413 (see FIG. 9) located in the stretchable area 102. The third metal structure 413 may be located between the two second metal structures 412, and may be spaced apart from the second metal structures 412, and support the first metal structure 411. The width of the third metal structure 413 along the first preset direction D1 may be greater than 3 microns to ensure the tensile stability of the third metal structure 413. The first elastic metal structure 41 may be integrally formed. That is, the first metal structure 411, the second metal structure 412, and the third metal structure 413 are integrally formed to improve the stability of the first elastic metal structure 41.

The display panel may further include an stretchable substrate 50 located in a side of the pixel definition layer 10 away from the conductive isolation structure 30, and the stretchable substrate 50 may include a flexible substrate 51 provided in the stretchable area 102 and a non-flexible substrate 52 provided in the island area 101. The material and thickness of the stretchable substrate 50 are not limited here and can be selected according to actual needs.

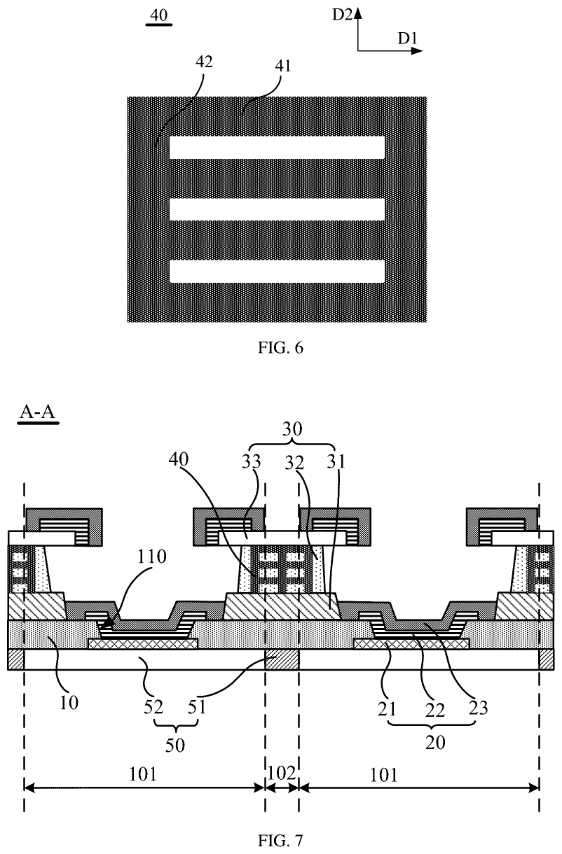

Please refer to FIG. 2, FIG. 4 to FIG. 6, FIG. 6 is a schematic structural top plan view of an elastic metal structure of a second embodiment of a display panel provided by the present disclosure.

The second embodiment of the display panel provided by the present disclosure has a substantially same structure as the first embodiment of the display panel provided by the present disclosure, except that the elastic metal structure 40 in the second embodiment may further include a second elastic metal structure 42 located in the island area 101.

In this embodiment, the elastic metal structure 40 may further include the second elastic metal structure 42 located in the island area 101, the second elastic metal structure 42 may be located between two adjacent first elastic metal structures 41, and be configured to connect the first metal structures 411 adjacent to each other in the second preset direction D2, and to connect the second metal structures 412 adjacent to each other in the second preset direction D2.

The second elastic metal structure 42 may be located in the end of the first elastic metal structure 41 along the first preset direction D1. The second metal structure 412 and the second elastic metal structure 42 located in the same side of the first elastic metal structure 41 along the first preset direction D1 are located in the same straight line to reduce the width of the elastic metal structure 40 in the middle insulating part 32, so as not to affect the distance of the sub-pixels 20 with each other; secondly, the second elastic metal structure 42 and the first elastic metal structure 41 are integrally formed, and the second metal structure 412 and the second elastic metal structure 42 located at the same side of the first elastic metal along the first preset direction D1 are located at the same straight line, which may improve the stability of the second metal structure 412 and the second elastic metal structure 42.

Mesh connection of the elastic metal structures 40 may be achieved through the connection of the first elastic metal structure 41 and the second elastic metal structure 42 with each other, which may further improve the stability of the elastic metal structure 40.

That is to say, compared with the first embodiment of the display panel provided by the present disclosure, the mesh connection of the elastic metal structures 40 in this embodiment may further improve the stability of the elastic metal structure 40, and therefore improve the tensile stability of the conductive isolation structure 30 as a whole.

In other embodiments, the first elastic metal structure 41 may further include the first metal structure 411, the second metal structure 412, and the third metal structure 413 (see FIG. 9).

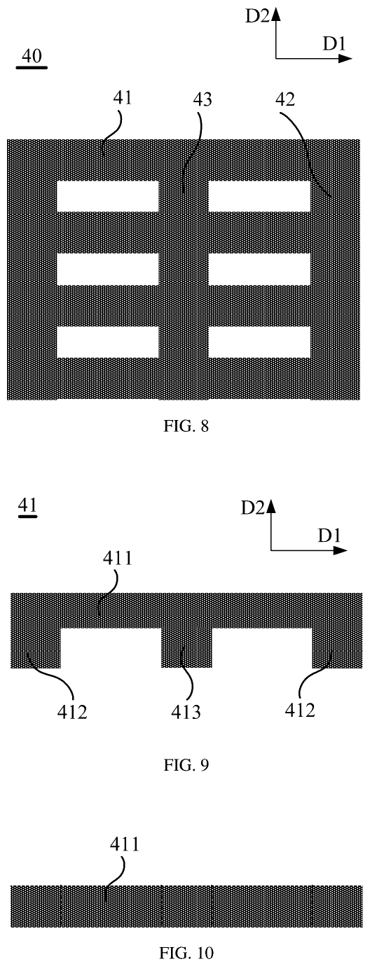

Please refer to FIG. 7 to FIG. 10, FIG. 7 is a schematic structural diagram of a third embodiment of a display panel provided by the present disclosure, FIG. 8 is schematic structural top plan view of an elastic metal structure in FIG. 7, FIG. 9 is a schematic longitudinal cross-sectional structural view of a first elastic metal structure in FIG. 7, and FIG. 10 is a schematic structural top plan view of a first elastic metal structure in FIG. 7.

The third embodiment of the display panel provided by the present disclosure has a substantially same structure as the second embodiment of the display panel provided by the present disclosure, except that the elastic metal structure 40 in the third embodiment may further include a third elastic metal structure 43 located in the stretchable area 102, and the first elastic metal structure 41 in the third embodiment may further include a third metal structure 413.

In this embodiment, the elastic metal structure 40 may further include a third elastic metal structure 43 located in the stretchable area 102. The third elastic metal structure 43 may be located between two adjacent first elastic metal structures 41 and be configured to achieve the connection of the first metal structures 411 which are adjacent in the second preset direction D2.

The third metal structure 413 may be located in the middle of the first metal structure 411, and the third elastic metal structure 43 may be connected to the middle of the first metal structure 411 and to the third metal structure 413. Similarly, mesh connection of the elastic metal structure 40 may be achieved through connection of the first elastic metal structure 41, the second elastic metal structure 42 and the third elastic metal structure 43 with each other, which may further improve the stability of the elastic metal structure 40.

That is to say, compared with the second embodiment of the display panel provided by the present disclosure, the mesh connection of the elastic metal structure 40 in this embodiment is denser, which may further improve the stability of the elastic metal structure 40, and therefore improve the tensile stability of the conductive isolation structure 30 as a whole.

In other embodiments, the first elastic metal structure 41 may not include the third metal structure 413.

The present disclosure provides a display device, which includes the above-mentioned display panel.

In the above embodiments, the description of each embodiment has its own emphasis, for parts that are not described in detail in a certain embodiment, reference can be made to the relevant descriptions of other embodiments.

The above are only implementation methods of the present disclosure, and are not intended to limit the protection scope of the present disclosure, any transformation of equivalent structures or equivalent process made using the contents of specification and figures in the present disclosure, or directly or indirectly using of the contents of specification and figures in the present disclosure in other related technical fields, are also included in the protection scope of the present disclosure.

What is claimed is:

1. A display panel, defining an island area and a stretchable area located at a side of the island area, and comprising:
a pixel definition layer, covering the island area and the stretchable area; the pixel definition layer having a pixel aperture located at the island area, the pixel aperture and an adjacent pixel aperture being arranged at intervals;
a sub-pixel, located in the pixel aperture;
a conductive isolation structure, protruded from the pixel definition layer and located at a side of the sub-pixel; wherein the conductive isolation structure comprises a conductive part, a middle insulating part and a top insulating part which are sequentially stacked in a direction away from the pixel definition layer; the conductive isolation structure is located at the island area and the stretchable area; the conductive part is provided in contact with and conductive to a cathode of the adjacent sub-pixel;
wherein, the display panel further includes an elastic metal structure embedded in the middle insulating part and electrically connected to the conductive part; the elastic metal structure includes at least one first elastic metal structure; the first elastic metal structure includes a first metal structure at least located at the stretchable area and a second metal structure located at the island area; the first metal structure is extended along a first preset direction, and the second metal structure supports the first metal structure along a thickness direction of the pixel definition layer; the first preset direction is perpendicular to the thickness direction of the pixel definition layer and parallel to a plane direction of the pixel definition layer.

2. The display panel according to claim 1, wherein a plurality of the elastic metal structures are stacked and aligned in the thickness direction of the pixel definition layer; and the plurality of the elastic metal structures are electrically connected with each other.

3. The display panel according to claim 2, wherein the number of the first elastic metal structures is a plurality; the plurality of first elastic metal structures are arranged at intervals along a second preset direction; the second preset direction intersects with the first preset direction, and the second preset direction is parallel to the plane direction of the pixel definition layer.

4. The display panel according to claim 3, wherein the second metal structure is located at a side of the first metal structure close to the pixel definition layer and is extended along the thickness direction of the pixel definition layer; the number of the second metal structures in the first elastic metal structure is two, and the two second metal structures are arranged side by side and at intervals along the first preset direction, and the two second metal structures are respectively connected to the ends of the first metal structure.

5. The display panel according to claim 4, wherein the first elastic metal structure further includes a third metal structure located at the stretchable area; the third metal structure is located between two second metal structures, and is spaced apart from the second metal structure, and supports the first metal structure.

6. The display panel according to claim 3, wherein a height of the second metal structure is 1 micron to 1.5 microns, a width of the second metal structure is 3 microns to 4 microns, and a thickness of the first metal structure is 3000 angstroms to 5000 angstroms.

7. The display panel according to claim 4, wherein the elastic metal structure further includes a second elastic metal structure located at the island area, and the second elastic metal structure is located between two adjacent first elastic metal structures, configured to connect the first metal structures adjacent to each other in the second preset direction, and connect the second metal structures adjacent to each other in the second preset direction.

8. The display panel according to claim 5, wherein the elastic metal structure further includes a second elastic metal structure located at the island area, and the second elastic metal structure is located between two adjacent first elastic metal structures, configured to connect the first metal structures adjacent to each other in the second preset direction, and connect the second metal structures adjacent to each other in the second preset direction.

9. The display panel according to claim 7, wherein the elastic metal structure further includes a third elastic metal structure located at the stretchable area; the third elastic metal structure is located between two adjacent first elastic metal structures, configured to connect the first metal structures adjacently arranged in the second preset direction.

10. The display panel according to claim 8, wherein the elastic metal structure further includes a third elastic metal structure located at the stretchable area; the third elastic metal structure is located between two adjacent first elastic metal structures, configured to connect the first metal structures adjacently arranged in the second preset direction.

11. The display panel according to claim 1, wherein the first elastic metal structure is an integrally formed structure.

12. A display device, comprising a display panel, wherein the display panel defines an island area and a stretchable area located at a side of the island area, and comprises:
a pixel definition layer, covering the island area and the stretchable area; the pixel definition layer having a pixel aperture located at the island area, the pixel aperture and an adjacent pixel aperture being arranged at intervals;
a sub-pixel, located in the pixel aperture;
a conductive isolation structure, protruded from the pixel definition layer and located at a side of the sub-pixel; wherein the conductive isolation structure comprises a conductive part, a middle insulating part and a top insulating part which are sequentially stacked in a direction away from the pixel definition layer; the conductive isolation structure is located at the island area and the stretchable area; the conductive part is provided in contact with and conductive to a cathode of the adjacent sub-pixel;
wherein, the display panel further includes an elastic metal structure embedded in the middle insulating part and electrically connected to the conductive part; the elastic metal structure includes at least one first elastic metal structure; the first elastic metal structure includes a first metal structure at least located at the stretchable area and a second metal structure located at the island area; the first metal structure is extended along a first preset direction, and the second metal structure supports the first metal structure along a thickness direction of the pixel definition layer; the first preset direction is perpendicular to the thickness direction of the pixel definition layer and parallel to a plane direction of the pixel definition layer.

13. The display device according to claim 12, wherein a plurality of the elastic metal structures are stacked and aligned in the thickness direction of the pixel definition layer; and the plurality of the elastic metal structures are electrically connected with each other.

14. The display device according to claim 13, wherein the number of the first elastic metal structures is a plurality; the plurality of first elastic metal structures are arranged at intervals along a second preset direction; the second preset direction intersects with the first preset direction, and the second preset direction is parallel to the plane direction of the pixel definition layer.

15. The display device according to claim 14, wherein the second metal structure is located at a side of the first metal structure close to the pixel definition layer and is extended along the thickness direction of the pixel definition layer; the number of the second metal structures in the first elastic metal structure is two, and the two second metal structures are arranged side by side and at intervals along the first preset direction, and the two second metal structures are respectively connected to the ends of the first metal structure.

16. The display device according to claim 15, wherein the first elastic metal structure further includes a third metal structure located at the stretchable area; the third metal structure is located between two second metal structures, and is spaced apart from the second metal structure, and supports the first metal structure.

17. The display device according to claim 14, wherein a height of the second metal structure is 1 micron to 1.5 microns, a width of the second metal structure is 3 microns to 4 microns, and a thickness of the first metal structure is 3000 angstroms to 5000 angstroms.

18. The display device according to claim 15, wherein the elastic metal structure further includes a second elastic metal structure located at the island area, and the second elastic metal structure is located between two adjacent first elastic metal structures, configured to connect the first metal structures adjacent to each other in the second preset direction, and connect the second metal structures adjacent to each other in the second preset direction.

19. The display device according to claim 18, wherein the elastic metal structure further includes a third elastic metal structure located at the stretchable area; the third elastic metal structure is located between two adjacent first elastic metal structures, configured to connect the first metal structures adjacently arranged in the second preset direction.

20. The display device according to claim 12, wherein the first elastic metal structure is an integrally formed structure.
